(19) United States
(12) Patent Application Publication
(10) Pub. No.: US 2025/0158598 A1
(43) Pub. Date: May 15, 2025

(54) SIGNAL SAMPLING DEVICE FOR LOW VOLTAGE APPLICATIONS

(71) Applicant: SigmaStar Technology Ltd., Xiamen (CN)

(72) Inventors: Ling Ling ZHANG, Shanghai (CN); Zhen Yang PANG, Shanghai (CN); Yuan Yuan YANG, Shanghai (CN)

(21) Appl. No.: 18/926,559

(22) Filed: Oct. 25, 2024

(30) Foreign Application Priority Data
Nov. 10, 2023 (CN) 202311503036.7

(51) Int. Cl. H03K 3/037; H03K 17/56

(52) U.S. Cl. CPC H03K 3/037; H03K 17/56

(57) ABSTRACT

A signal sampling device includes an input circuit and a latch circuit. The input circuit is activated in a first period according to a first clock signal to generate a plurality of first output signals according to a plurality of input signals. The latch circuit is activated in a second period according to a second clock signal to generate a plurality of second output signals according to the plurality of first output signals,

This application claims the benefit of China application Serial No. CN 202311503036.7, file on Nov. 10, 2023, the subject matter of which is incorporated herein by reference.

### BACKGROUND OF THE INVENTION

### Field of the Invention

The present application relates to a signal sampling device, and more particularly to a signal sampling device capable of effectively increasing a gain of a latch in a low-voltage environment.

### Description of the Related Art

In general, a latch circuit is configured to have a circuit structure including multiple cascaded transistors to thereby increase an amplification gain. However, the circuit structure above is unsuitable for low-voltage application environments. In some related art, in order to adapt to low-voltage environments, a sampling amplifier having a two-tail current source is used an alternative to sample data signals. However, in the technique above, since data sampling in a low-voltage environment may need a greater amount of time, it is possible that a latch of a sampling amplifier may fail to adequately amplify sampled data signals to a more obvious amplitude difference within an original operating period.

### SUMMARY OF THE INVENTION

In some embodiments, it is an object of the present application to provide a signal sampling device capable of effectively increasing a gain of a latch in a low-voltage environment so as to improve the issues of the prior art.

In some embodiments, the signal sampling device includes an input circuit and a latch circuit. The input circuit is activated in a first period according to a first clock signal to generate a plurality of first output signals according to a plurality of input signals. The latch circuit is activated in a second period according to a second clock signal to generate a plurality of second output signals according to the plurality of first output signals, wherein the second period is later than the first period.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 is a schematic diagram of a signal sampling device according to some embodiments of the present application;

FIG. 2 is a schematic diagram of a sampling amplifier in FIG. 1 according to some embodiments of the present application;

FIG. 3 is a schematic diagram of waveforms of multiple signals in FIG. 2 according to some embodiments of the present application; and

FIG. 4 is a schematic diagram of a corrector in FIG. 1 according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

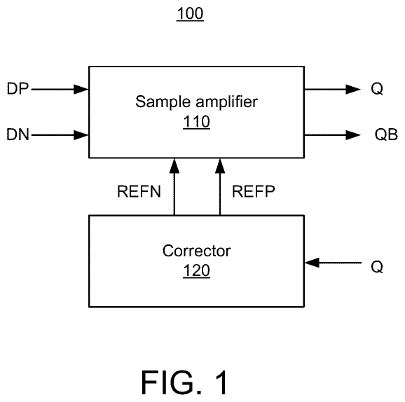

FIG. 1 shows a schematic diagram of a signal sampling device 100 according to some embodiments of the present application. In some embodiments, the signal sampling device 100 may include a sampling amplifier 110 and a corrector 120. The sampling amplifier 110 may sample multiple input signals DP and DN, and accordingly generate multiple output signals Q and QB. The corrector 120 may be used to correct an offset in the sampling amplifier 110. In some embodiments, the offset is caused by non-ideal factors such as manufacturing variations, voltage variations and temperature variations. In some embodiments, the corrector 120 may generate multiple reference voltages REFP and REFN according to the output signal Q, so as to correct levels of internal nodes of the sampling amplifier 110 to thereby reduce influences of the offset.

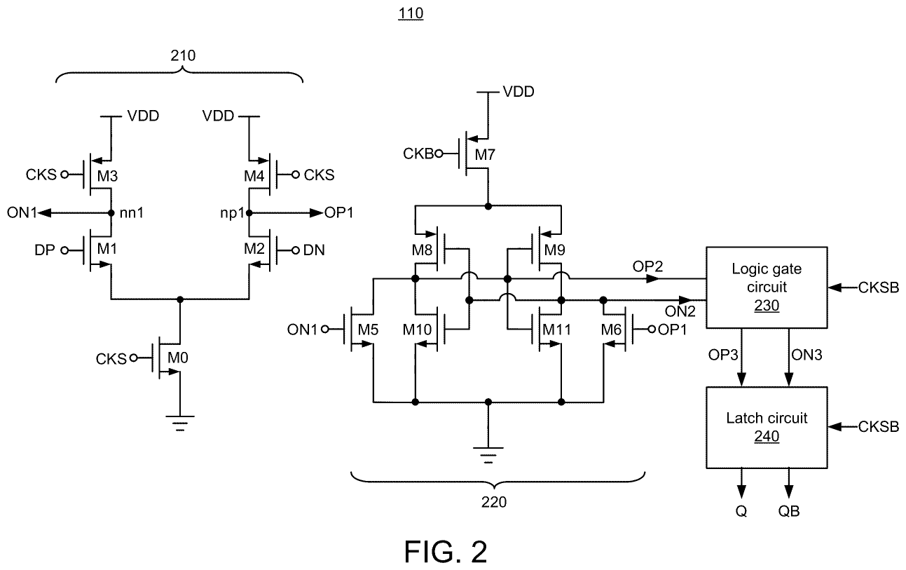

FIG. 2 shows a schematic diagram of the sampling amplifier 110 in FIG. 1 according to some embodiments of the present application. The sampling amplifier 110 includes an input circuit 210, a latch circuit 220, a logic gate circuit 230 and a latch circuit 240.

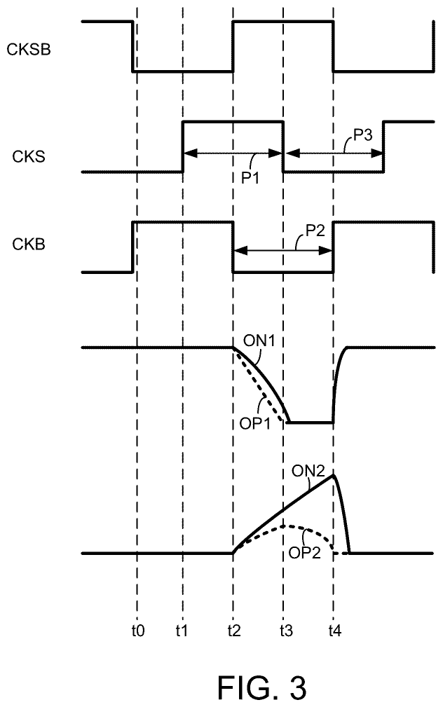

The input circuit 210 is activated in a first period (for example, the period P1 in FIG. 3) according to a clock signal CKS, so as to generate multiple output signals OP1 and ON1 according to the multiple input signals DP and DN. The input circuit 210 may further reset levels of the multiple output signals OP1 and ON1 according to the clock signal CKS. More specifically, the input circuit 210 includes multiple transistors M0 to M4, wherein the multiple transistors M3 and M4 are P-type transistors, and the multiple transistors M0 to M2 are N-type transistors. A first terminal (for example, a drain) of the transistor M0 is coupled to second terminals (for example, sources) of the multiple transistors M1 and M2, a second terminal of the transistor M0 is coupled to ground, and a control terminal (for example, a gate) of the transistor M0 receives the clock signal CKS. A first terminal of the transistor M1 is coupled to a node nn1 and generates the output signal ON1, and a control terminal of the transistor M1 receives the input signal DP. A first terminal of the transistor M2 is coupled to a node np1 and generates the output signal OP1, and a control terminal of the transistor M2 receives the input signal DN. A first terminal (for example, a source) of the transistor M3 receives a voltage VDD, a second terminal (for example, a drain) of the transistor M3 is coupled to the node nn1, and a control terminal of the transistor M3 receives the clock signal CKS. A first terminal of the transistor M4 receives the voltage VDD, a second terminal of the transistor M4 is coupled to the node np1, and a control terminal of the transistor M4 receives the clock signal CKS.

With the configuration above, when the clock signal CKS is at a disable level (for example, a low level), the transistor M0 is turned off and the transistor M3 and the transistor M4 are turned on. In this case, levels of the node nn1 and the node np1 are reset to the voltage VDD. In other words, when the clock signal CKS is at a disable level, the input circuit 210 may reset the levels of the multiple output signals OP1 and ON1 to the voltage VDD. On the other hand, when the clock signal CKS is at an enable level (for example, a high level), the transistor M0 is turned on and the transistor M3 and the transistor M4 are turned off. In this case, the multiple transistors M1 and M2 are driven by the transistor M0, and levels of the multiple nodes nn1 and np1 are selectively adjusted according to the multiple input signals DP and DN to thereby generate the multiple output signals OP1 and ON1. In some embodiments, levels of the input signal DP and the input signal DN may be defined by a common-mode voltage. In the description below, if the input signal DP (or the input signal DN) is described as being at a high level, it means that the level of the input signal DP (or the input signal DN) is higher than the common-mode voltage. Similarly, if the input signal DP (or the input signal DN) is described as being at a low level, it means that the level of the input signal DP (or the input signal DN) is lower than the common-mode voltage. In this embodiment, the transistor M1 is turned on regardless of whether the input signal DP is at a high level or at a low level; however, the level of conduction of the transistor M1 is lower when the input signal DP is at a low level. Similarly, the transistor M2 is turned on regardless of whether the input signal DN is at a high level or at a low level; however, the level of conduction of the transistor M2 is lower when the input signal DN is at a low level. When one between the input signal DP and the input signal DN is at a high level and the other is at a low level, the levels of the node np1 and the node nn1 are both pulled down to ground. As such, the input circuit 210 may generate the output signal ON1 and the output signal OP1 at a low level. In some embodiments, if the node nn1 is pulled down to ground via the transistor M1 having a lower level of conduction and a node nn2 is pulled down to ground via the transistor M2 having a higher level of conduction, the level of the node nn1 is also pulled down to ground more slowly (compared to the node nn2); and vice versa.

The latch circuit 220 is activated in a second period (for example, the period P2 in FIG. 3) according to the clock signal CKB, so as to generate multiple output signals OP2 and ON2 according to the multiple output signals OP1 and ON1. The latch circuit 220 may further reset levels of the multiple output signals OP2 and ON2 according to a clock signal CKB. More specifically, the latch circuit 220 includes multiple transistors M5 to M11, wherein the multiple transistors M7 and M9 are P-type transistors, and the multiple transistors M5, M6, M10 and M11 are N-type transistors. A first terminal of the transistor M5 is coupled to a second terminal of the transistor M8, a first terminal of the transistor M10 and control terminals of the multiple transistors M9 and M11, and generates the output signal OP2. A second terminal of the transistor M5 is coupled to ground, and a control terminal of the transistor M5 is coupled to the node nn1 so as to receive the output signal ON1. A first terminal of the transistor M6 is coupled to a second terminal of the transistor M9, a first terminal of the transistor M11 and control terminals of the multiple transistors M8 and M10, and generates the output signal ON2. A second terminal of the transistor M6 is coupled to ground, and a control terminal of the transistor M6 is coupled to the node np1 so as to receive the output signal OP1. A first terminal of the transistor M7 receives the voltage VDD, a second terminal of the transistor M7 is coupled to first terminals of the multiple transistors M8 and M9, and a control terminal of the transistor M7 receives the clock signal CKB. Second terminals of the multiple transistors M8 and M11 are coupled to ground.

With the configuration above, the transistor M8 and the transistor M10 may form an inverter, and the transistor M9 and the transistor M11 may form another inverter, wherein the two inverters are cross-coupled so as to form a latch. When the transistor M7 is turned on according to the clock signal CKB (that is, when the latch circuit 220 is activated), the two inverters above are driven by the transistor M7 to thereby generate the multiple corresponding output signals OP2 and ON2 according to the output signals OP1 and ON1.

The logic gate circuit 230 generates multiple output signals OP3 and ON3 according to the multiple output signals OP2 and ON2 and a clock signal CKSB. In some embodiments, the logic gate circuit 230 may include a first logic gate (not shown) and a second logic gate (not shown). The first logic gate may generate the output signal OP3 according to the output signal OP2 and the clock signal CKSB, and the second logic gate may generate the output signal ON3 according to the output signal ON2 and the clock signal CKSB. In some embodiments, the first and second logic gates may be NAND gates; however, the present application is not limited to the example above. The latch circuit 240 generates multiple output signals OP4 and ON4 according to the multiple output signals OP3 and ON3 and the clock signal CKSB. In some embodiments, the latch circuit 240 may include a first latch (not shown) and a second latch (not shown). The first latch may generate the output signal Q according to the output signal OP3 and the clock signal CKSB, and the second latch may generate the output signal QB according to the output signal ON3 and the clock signal CKSB. In some embodiments, the first and second latches may be D type flip-flops; however, the present application is not limited to the example above.

In some embodiments, the sampling amplifier 110 may further include a clock generating circuit (not shown), which may generate the clock signal CKSB, the clock signal CKS and the clock signal CKB having the same cycle but sequentially differing by a predetermined time difference.

FIG. 3 shows a schematic diagram of waveforms of multiple signals in FIG. 2 according to some embodiments of the present application. At a timing t0, the clock signal CKS is at a disable level (for example, a low level), and the clock signal CKB is at a disable level (for example, a high level). In this case, the transistor M0 and the transistor M7 are turned off, and the transistor M3 and the transistor M4 are turned on. Accordingly, the levels of the node nn1 and the node np1 are reset to the voltage VDD via the multiple transistors M3 and M4, thereby outputting the output signal OP1 and the output signal ON1 at a level of the voltage VDD. Thus, the transistor M5 and the transistor M6 are turned on according to the output signal OP1 and the output signal ON1, thereby resetting the levels of the output signal OP2 and the output signal ON2 to ground. In other words, at the timing to, the input circuit 210 and the latch circuit 220 reset the levels of the multiple output signals OP1, ON1, OP2 and ON2.

At a timing t1, the clock signal CSK switches to an enable level (for example, a high level), and the clock signal CKB is still kept at a disable level. In this case, the transistor M0 becomes turned on, and the multiple transistors M3, M4 and M7 are turned off. Thus, the transistor M0 may drive the transistor M1 and the transistor M2 (that is, the input circuit 210 is activated), such that the transistor M1 and the transistor M2 may be selectively turned on according to the input signals DP and DN. For example, if the input signal DN is at a high level and the input signal DP is at a low level, the transistor M1 is turned on (with a lower level of conduction) such that the output signal ON1 is gradually pulled down to ground, and the transistor M2 is turned on (with a high level of conduction) so as to pull down the level of the output signal OP1 to ground. On the other hand, the latch circuit 220 remains inactivated because the transistor M7 remains turned off.

At a timing t2, the clock signal CSK is kept at an enable level, and the clock signal CKB switches to an enable level (for example, a low level). In this case, the transistor M7 is turned on such that the latch circuit 220 is activated. Since the level of the output signal ON1 is gradually pulled down to ground level, the level of conduction of the transistor M5 gradually decreases such that the level of the output signal OP2 is primarily determined by the first inverter formed by the transistor M8 and the transistor M10. On the other hand, since the level of the output signal OP1 is also pulled down to ground, the transistor M6 is turned off, such that the level of the output signal ON2 is determined by the second inverter formed by the transistor M9 and the transistor M11.

It should be noted that, as described previously, the levels of both of the output signal OP2 and the output signal ON2 are reset to ground level at the timing to. Thus, at a timing t2, the first inverter and the second inverter generate, according to the output signal OP2 and the output signal ON2 at ground level, the output signal OP2 and the output signal ON2 of which levels increase gradually. However, as described previously, the transistor M5 is not completely turned off due to slow decreasing speed of the level of the output signal ON1 (that is, the node nn1 is pulled down to ground by the transistor M1 having a lower level of conduction), such that the level of the output signal OP2 is pulled down continually by the transistor M5 having a lower level of conduction. Thus, the level of the output signal OP2 increases at a slower speed. Next, when the level of the output signal ON2 increases to a transition point (for example, a timing t3) of the inverter, the first inverter switches to generating the output signal OP2 of which the level decreases gradually. In other words, during an operating period (for example, a period P2) of the latch circuit 220, with the cross-coupled first and second inverters, the level of the output signal OP2 decreases if the level of the output signal ON increases, and vice versa.

At the timing t3, the clock signal CSK switches to a disable level, and the clock signal CKB is still kept at an enable level. In this case, the input circuit 210 again starts performing the operations of resetting the levels of the output signals OP1 and ON1 (the same operations at the timing t0). On the other hand, the level of the output signal ON2 is pulled up continually by the second inverter formed by the transistors M9 and M11 at the timing t3. In other words, when the input circuit 210 starts resetting the levels of the output signal OP1 and the output signal ON1 according to the clock signal CKS at the timing t3, the latch circuit 220 may continue generating the output signal OP2 and the output signal ON2.

At a timing t4, the clock signal CSK is kept at a disable level, the clock signal CKB switches to a disable level, and the clock signal CKSB is at an enable level (for example, a high level). Thus, the transistor M7 is turned off (that is, the latch circuit 220 switches to be inactivated), such that the levels of the output signal ON2 and the output signal OP2 may start to be reset by the transistor M5 and the transistor M6. On the other hand, the level of the output signal ON2 is pulled up to a highest level by the second inverter at the timing t4. As such, at the timing t4, in response to the clock signal CKSB at an enable level, the logic gate circuit 230 may read the output signal ON2 at a higher level.

In the operations above, the input circuit 210 is activated in the period P1 so as to generate the output signals OP1 and ON1 according to the input signals DP and DN. The latch circuit 220 is activated in the period P2 so as to generate the output signals OP2 and ON2 according to the output signals OP1 and ON1, wherein the period P1 and the period P2 have a same time length but the period P2 is later than the period P1. In other words, the clock signal CKS and the clock signal CKB have the same cycle and a start timing (for example, the timing t2) of the period P2 is later than a start timing (for example, t1) of the period P1, such that the input circuit 210 and the latch circuit 220 have operating periods (that is, the period P1 and the period P2) of the same time length, and the period P1 and the time period P2 partially overlap. On the other hand, as described previously, at the timing to, the clock signal CKS switches to a disable level (for example, a low level), such that the input circuit 210 and the latch circuit 220 reset the levels of the multiple output signals OP1, ON1, OP2 and ON2. In other words, a low-level period of the clock signal CKS is a period (denoted as a period P3) in which the multiple circuits above reset the corresponding output signals, and this period and the period P2 also partially overlap.

With the configuration above, an activation timing (for example, the timing 2) of the latch circuit 220 may be later than an activation timing (for example, the timing t1) of the input circuit 210, so that the latch circuit 220 may continue pulling down the level of the output signal ON2 (that is, an operation corresponding to the period P2) while the levels of both of the output signal OP1 and the output signal ON1 are being pulled down, so as to generate the output signal ON2 having an obvious amplitude difference. Equivalently speaking, the configuration above is able to achieve a greater amplification gain by adjusting the operating period of the latch circuit 220, thereby generating more complete data signals in a low-voltage environment.

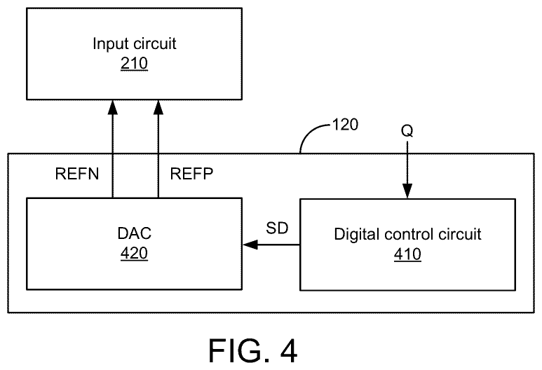

FIG. 4 shows a schematic diagram of the corrector 120 in FIG. 1 according to some embodiments of the present application. As described previously, the corrector 120 may generate the multiple reference voltages REFP and REFN according to the output signal Q, so as to correct a level of an internal node of the sampling amplifier 110. For example, the corrector 120 may generate the multiple reference voltages REFP and REFN according to the output signal Q, and use the multiple reference signals REFP and REFN to correct the levels of the node nn1 and the node np1 in the input circuit 210 that are used to generate the output signal OP1 and the output signal ON1. In some embodiments, the corrector 120 includes a digital control circuit 410 and a digital-to-analog converter (DAC) 420. The digital control circuit 410 may perform a predetermined algorithm according to the output signal Q (which may be used to indicate a difference between the input signal DP and the input signal DN) to generate a digital code SD. In some embodiments, the predetermined algorithm may be, for example but not limited to, a successive approximation register (SAR) algorithm. The DAC 420 may generate the multiple reference voltages REFP and REFN according to the digital code SD, and accordingly use the multiple reference voltages REFP and REFN to adjust the levels of the multiple nodes nn1 and np1.

In some embodiments, the DAC 420 may include multiple resistive ladder (R-2R) networks (not shown), multiple switches (not shown) and a decoder (not shown). The decoder may decode the digital code to generate multiple control signals. The multiple switches may perform switching according to these multiple control signals to thereby adjust a connection relationship between the multiple resistive ladder networks, and divide a system voltage via these resistive ladder networks so as to obtain the corresponding reference voltage REFP and reference voltage REFN. In some embodiments, the DAC 420 may further include multiple current sources, which may generate multiple corresponding current signals according to the reference voltage REFP and the reference voltage REFN, and transmit the current signals to the node nn1 and the node np1 to thereby adjust the levels of the multiple nodes nn1 and np1.

It should be noted that the configuration details of the DAC 420 above are examples, and are not to be construed as limitation to the present application. Various related configurations operable to correct the offset in the sampling amplifier 110 according to the difference between the input signal DP and the input signal DN are to be encompassed within the scope of the present application.

In conclusion, the signal sampling device according to some embodiments of the present application is capable of adjusting an activation timing of a secondary circuit (for example, the latch circuit) in the signal sampling device so as to equivalently increase the gain of the secondary circuit, thereby generating signals having sufficient amplitudes in a low-voltage environment.

While the present application has been described by way of example and in terms of the preferred embodiments, it is to be understood that the disclosure is not limited thereto. Various modifications made be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. A signal sampling device, comprising:
an input circuit, activated in a first period according to a first clock signal to generate a plurality of first output signals according to a plurality of input signals; and
a first latch circuit, activated in a second period according to a second clock signal to generate a plurality of second output signals according to the plurality of first output signals, wherein the second period is later than the first period.

2. The signal sampling device according to claim 1, wherein the first period and the second period have a same time length.

3. The signal sampling device according to claim 1, wherein when the input circuit starts to reset levels of the plurality of first output signals according to the first clock signal, the first latch circuit starts to generate the plurality of second output signals.

4. The signal sampling device according to claim 1, wherein a period in which the input circuit resets the plurality of first output signals and the second period partially overlap.

5. The signal sampling device according to claim 1, wherein the first period and the second period partially overlap.

6. The signal sampling device according to claim 1, further comprising:
a logic gate circuit, generating a plurality of third output signals according to the plurality of second output signals and a third clock signal.

7. The signal sampling device according to claim 6, further comprising:
a second latch circuit, generating a plurality of fourth output signals according to the third clock signal and the plurality of third output signals.

8. The signal sampling device according to claim 7, further comprising:
a corrector, correcting, according to one of the plurality of fourth output signals, levels of a plurality of nodes in the input circuit that are used to output the plurality of first output signals.

9. The signal sampling device according to claim 8, wherein the corrector comprises:
a digital control circuit, generating a digital code according to the one of the plurality of fourth output signals; and
a digital-to-analog converter (DAC), generating a plurality of reference voltages according to the digital code so as to correct the levels of the plurality of nodes.

10. The signal sampling device according to claim 6, wherein the third clock signal, the second clock signal and the first clock signal have a same cycle.
